(19) United States
(12) Patent Application Publication
(10) Pub. No.: US 2008/0261122 A1
(43) Pub. Date: Oct. 23, 2008

(54) PHOTOLITHOGRAPHY MASK WITH PROTECTIVE CAPPING LAYER

(76) Inventors: Jeffrey Peter Gambino, Westford, VT (US); Robert Kenneth Leidy, Burlington, VT (US); Kirk David Peterson, Jericho, VT (US); Jed Hickory Rankin, Richmond, VT (US); Edmund Juris Sprogis, Underhill, VT (US)

Correspondence Address: SCHMEISER, OLSEN & WATTS, 22 CENTURY HILL DRIVE, SUITE 302, LATHAM, NY, 12110, US

(21) Appl. No.: 11/738,070

(22) Filed: Apr. 20, 2007

(51) Int. Cl. G03C 5/00; G03F 1/00

(52) U.S. Cl. 430/5; 430/322; 430/323; 430/324; 430/394

(57) ABSTRACT

A photomask and a method of fabricating the photomask. The photomask including: a substrate transparent to a selected wavelength or wavelengths of radiation, the substrate having a top surface and an opposite bottom surface, the substrate having a printable region and a non-printable region; the printable region having first opaque regions raised above the top surface of the substrate adjacent to clear regions, each opaque region of the first opaque regions having sidewalls and a top surface; the non-printable region comprising a second opaque region raised above the top surface of the substrate, the second opaque region having sidewalls and a top surface; and a capping layer on the sidewalls of the first opaque regions and the sidewalls of the second opaque region.

### FIELD OF THE INVENTION

The present invention relates to the field of photomasks for the manufacture of integrated circuits; more specifically, it relates to a photomask for the manufacture of integrated circuits and to a method of fabricating the photomask mask.

### BACKGROUND OF THE INVENTION

Integrated circuit fabrication utilizes photolithography masks having opaque and clear areas corresponding to features on an integrated circuit that the mask is used to fabricate. Generally several masks, each having a pattern of clear and opaque areas corresponding to a particular fabrication level are required to build a functional semiconductor device. In use, a photosensitive layer (hereinafter photoresist layer) on an integrated circuit substrate (hereinafter wafer) is exposed to optical radiation projected through the photomask to form latent images in the photoresist layer. After developing the photoresist layer, a positive or negative pattern (relative to the pattern of clear and opaque regions on the photomask) comprising islands of photoresist is reproduced on the wafer.

One type of photolithographic mask is called a binary mask (as opposed to a phase shift mask) in which there are two levels of transmission and no phase change of the radiation passing through the mask, one level in the opaque regions that essentially blocks the optical radiation and one level in the clear regions that passes the optical radiation.

A second type of mask is called an attenuated phase shift mask having three levels of transmission, one level in the opaque regions that essentially blocks the optical radiation, a second level in the clear regions that passes the optical radiation and a third level in semi-opaque regions that blocks about 94% of the optical radiation, but the optical radiation that is not blocked is phase shifted by 180 degrees compared to the optical radiation passing through the clear regions.

A third type of mask is called an alternative phase shift mask having three levels of transmission, one level in the clear regions that essentially blocks the optical radiation, a second level in clear regions that passes the optical radiation and a third level in thin substrate clear regions that passes and phase-shifts the optical radiation by 180 degrees compared to the optical radiation passing through the thin substrate clear regions.

In such masks, it is necessary to ensure that the relative transmission levels and/or optical radiation wavelength phase do not change if consistent image reproduction is to be consistent from wafer to wafer.

### SUMMARY OF THE INVENTION

A first aspect of the present invention is a photomask, comprising: a substrate transparent to a selected wavelength or wavelengths of radiation, the substrate having a top surface and an opposite bottom surface, the substrate having a printable region and a non-printable region; the printable region having first opaque regions raised above the top surface of the substrate adjacent to clear regions, each opaque region of the first opaque regions having sidewalls and a top surface; the non-printable region comprising a second opaque region raised above the top surface of the substrate, the second opaque region having sidewalls and a top surface; and a capping layer on the sidewalls of the first opaque regions and the sidewalls of the second opaque region.

A second aspect of the present invention is a method of fabricating a photomask, comprising: on a substrate transparent to a selected wavelength or wavelengths of radiation, the substrate having a top surface and an opposite bottom surface, defining a printable region and a non-printable region; forming in the printable region, first opaque regions raised above the top surface of the substrate adjacent to clear regions, each opaque region of the first opaque regions having sidewalls and a top surface; forming in the non-printable region, a second opaque region raised above the top surface of the substrate, the second opaque region having sidewalls and a top surface; and forming a capping layer on the sidewalls of the first opaque regions and the sidewalls of the second opaque region.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIGS. 1A through 1C are cross-sectional views illustrating fabrication of a binary photomask according to the present invention;

FIGS. 2A through 2C are cross-sectional views illustrating fabrication of an attenuated phase shift photomask according to the present invention; and

FIGS. 3A through 3C are cross-sectional views illustrating fabrication of an alternating phase shift mask photomask according to the present invention.

### DETAILED DESCRIPTION OF THE INVENTION

In a binary mask the opaque regions have, in one example, pass essentially none of a selected wavelength or group of wavelengths of optical radiation, i.e. the mask design wavelength(s) and the clear regions pass, in one example, about 99% or more of the optical radiation.

In a attenuated phase-shift mask, a small amount of radiation passes through the opaque regions (in one example, passing about 6% or less of the optical radiation) and undergoes a phase shift relative to the phase of the radiation passing through the clear regions (passing about 99% or more of the optical radiation).

In an alternating phase-shift mask, the radiation passing through the thinned clear regions (passing about 99% or more of the optical radiation) of the substrate undergoes a phase shift relative to the phase of the radiation passing through the non-thinned clear regions. The opaque regions have, in one example, an essentially zero radiation transmission level.

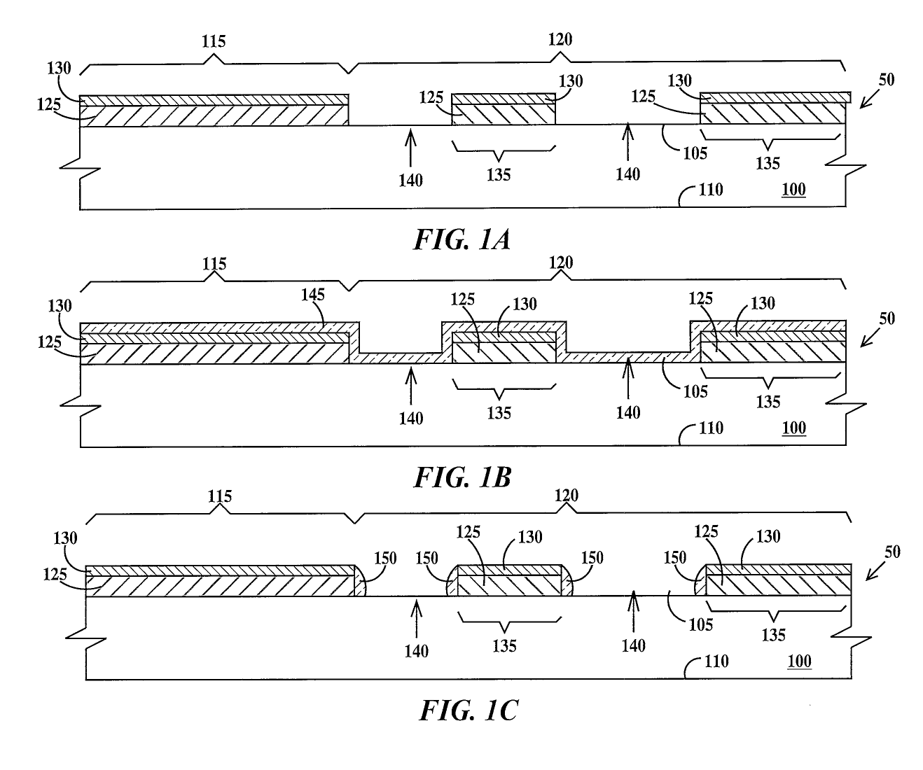

FIGS. 1A through 1C are cross-sectional views illustrating fabrication of a binary photomask according to the present invention. In FIG. 1A, a photomask 50 comprises a quartz or glass substrate 100 having a top surface 105 and a bottom surface 110. Photomask 50 includes a non-printable region 115 and a printable region 120. In one example, non-printable-region 115 surrounds the entire periphery of printable region 120. Non-printable region 115 comprises an opaque layer 125 on top surface 105 of substrate 100 and an anti-reflective layer 130 on a top surface of opaque layer 125. Formed in printable region 120 is a pattern of opaque regions 135 and clear regions 140 corresponding to a pattern of shapes to be transferred to a wafer by a photolithographic process using photomask 50. Each of opaque region 135 comprises opaque layer 125 and anti-reflective layer 130.

In one example, substrate 100 comprises quartz or glass. In one example, first opaque layer 125 is chrome formed by evaporation or sputter deposition. Chrome is particularly reactive under semiconductor device fabrication conditions and application of the embodiments of the present invention to chrome containing masks is particularly advantageous. In one example, opaque layer 125 is between about 300 Å and about 1000 Å thick. In one example, anti-reflective layer 130 is chrome oxide (CrO₂) or chromium oxynitride (Cr₂OₓN_{y}). In one example, anti-reflective layer 130 is between about 30 Å and about 500 Å thick.

The pattern of opaque regions 135 and clear regions 140 may be formed by (1) forming a chrome layer on the substrate, a chrome oxide layer on top of the chrome layer and a photoresist layer on top of the chrome oxide layer, (2) exposing selected regions of the photoresist layer to optical or e-beam radiation, (3) developing the photoresist layer, (4) etching away the chrome oxide and chrome where they not protected by photoresist, and (5) removing any remaining photoresist.

In FIG. 1B, a conformal capping layer 145 is formed on all exposed surfaces of opaque layer 125, anti-reflective layer 130 and exposed top surface 105 of substrate 100 in clear regions 140. Capping layer 145 is transparent to mask design wavelength(s) and thin to prevent attenuation of optical radiation. In one example, capping layer 145 comprises silicon dioxide (SiO₂). When capping layer 145 comprises SiO₂, it may be formed by plasma enhanced CVD (PECVD). In one example, capping layer 145 is between about 10 Å and about 50 Å thick. Capping layer 145 prevents the material (e.g. Cr) in opaque regions 135 from chemical attack and prevents the top surface of clear regions 140 from contamination. Capping layer 145 should be thick enough to prevent diffusion of underlying layers but thin enough not to block light.

In FIG. 1C, spacers (i. e. sidewall capping layers) 150 are formed from capping layer 145 using a reactive ion etch (RIE) to remove the capping layer from the top surface of antireflective layer 130 and from top surface 105 of substrate 100 in clear regions 140 (except where spacers 150 contact top surface 105 along the periphery of clear regions 140). When capping layer 145 is SIO₂, the RIE etch may be fluorine based. Spacers 150 completely cover all exposed edges of opaque layer 125.

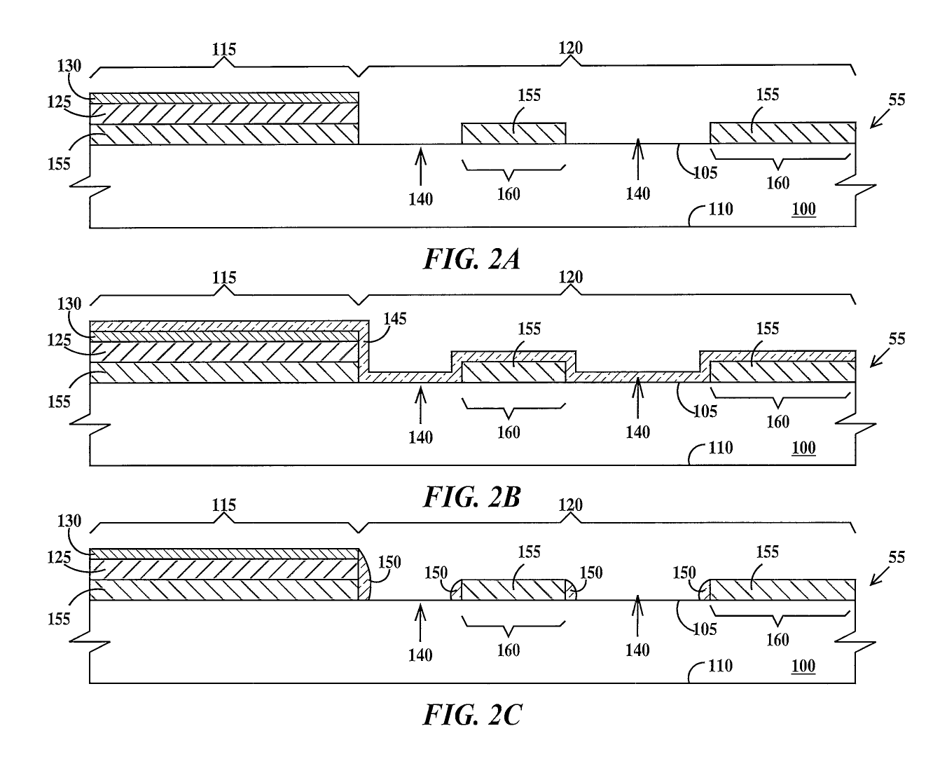

FIGS. 2A through 2C are cross-sectional views illustrating fabrication of an attenuated phase shift photomask according to the present invention. In FIG. 2A, a photomask 55 comprises substrate 100 having non-printable region 115 and printable region 120. Non-printable region 115 comprises an attenuating layer 155 on top surface 105 of substrate 100, an opaque layer 125 on a top surface of attenuating layer 155 and an anti-reflective layer 130 on the top surface of opaque layer 125. Formed in printable region 120 is a pattern of optical radiation attenuating regions 160 and clear regions 140 corresponding to a pattern of shapes to be transferred to a wafer by a photolithographic process using photomask 55. Each of attenuating regions 160 comprises attenuating layer 155.

In one example, attenuating layer 155 is between about 300 Å and about 1000 Å thick. In one example, attenuating layer 155 is molybdenum silicide (MoSi). In one example, anti-reflective layer 130 is between about 30 Å and about 500 Å thick.

The pattern of opaque regions 135 and clear regions 140 may be formed by (1) forming a molybdenum silicide layer on the substrate, forming a chrome layer on the molybdenum silicide, a chrome oxide layer on top of the chrome layer and a photoresist layer on top of the chrome oxide layer, (2) exposing selected regions of the photoresist layer to optical or e-beam radiation, (3) developing the photoresist layer, (4) etching away the chrome oxide, chrome and molybdenum silicide where they not protected by photoresist, (5) forming a second photoresist layer to protect the non-printable regions and (6) etching the exposed chrome oxide and chrome and (6) removing the second photoresist layer.

In FIG. 2B, conformal capping layer 145 is formed on all exposed surfaces of opaque layer 125, anti-reflective layer 130, attenuating layer 155 and on exposed top surface 105 of substrate 100 in clear regions 140.

In FIG. 2C, optionally, spacers 150 are formed by etching layer 145 with RIE. Spacers 150 completely cover all exposed edges of opaque layer 125.

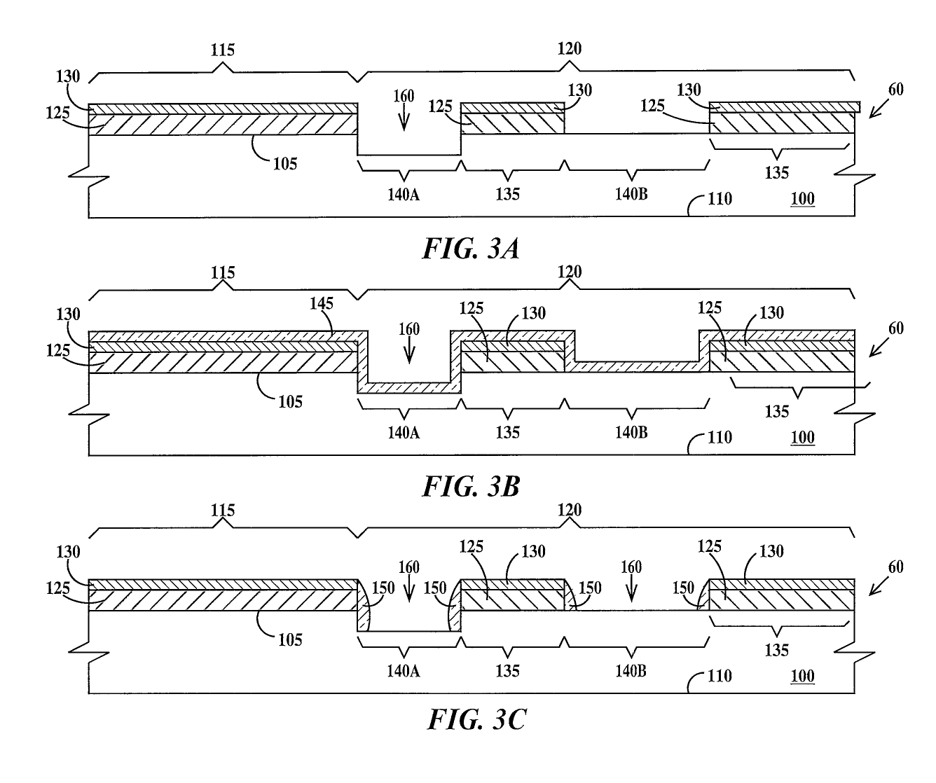

FIGS. 3A through 3C are cross-sectional views illustrating fabrication of an alternating phase shift mask photomask according to the present invention. In FIG. 3A, a photomask 60 comprises substrate 100 having non-printable region 115 and printable region 120. Non-printable region 115 comprises an opaque layer 125 and an anti-reflective layer 130 on the top surface of opaque layer 125. Formed in printable region 120 is a pattern of opaque regions 135, thinned clear regions 140A and clear regions 140B corresponding to a pattern of shapes to be transferred to a wafer by a photolithographic process using photomask 60.

Photomask 60 may be formed from photomask 50 illustrated in FIG. 1A and described supra by protecting some clear regions 140 (see FIG. 1A) with photoresist and etching into substrate 100 to form trenches 160 where an opening has been lithographically formed in the photoresist layer and then removing the photoresist.

In FIG. 3B, conformal capping layer 145 is formed on all exposed surfaces of opaque layer 125, opaque region 130, exposed top surface 105 of substrate 100 in clear regions 140 and the sidewalls and bottom of trenches 160.

In FIG. 3C, optionally, spacers 150 are formed. Spacers 150 completely cover all exposed edges of opaque layer 125.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A photomask, comprising:
a substrate transparent to a selected wavelength or wavelengths of radiation, said substrate having a top surface and an opposite bottom surface, said substrate having a printable region and a non-printable region;
said printable region having first opaque regions raised above said top surface of said substrate adjacent to clear regions, each opaque region of said first opaque regions having sidewalls and a top surface;
said non-printable region comprising a second opaque region raised above said top surface of said substrate, said second opaque region having sidewalls and a top surface; and
a protective capping layer on said sidewalls of said first opaque regions and said sidewalls of said second opaque region.

2. The photomask of claim 1, wherein said capping layer extends over said top surfaces of each region of said first opaque regions and said top surface of said second region and conformably covers said sidewalls of said second opaque region and said top surfaces and sidewalls of each region of said first opaque regions and said top surface and sidewalls of said second opaque region.

3. The photomask of claim 2, wherein said capping layer is transparent to said selected wavelength or wavelengths of radiation.

4. The photomask of claim 1, wherein said capping layer is silicon dioxide.

5. The photomask of claim 1, wherein:
each region of said first opaque regions comprises a layer of chrome oxide on a layer of chrome, said chrome layer on said top surface of said substrate; and
said second opaque region comprises said layer of chrome oxide on said layer of chrome.

6. The photomask of claim 1, wherein:
each region of said first opaque regions comprises a layer of molybdenum silicide, said molybdenum silicide layer on said top surface of said substrate; and
said second opaque region comprises a layer of chrome oxide on a layer of chrome on said layer of molybdenum silicide.

7. The photomask of claim 1, wherein:
each region of said first opaque regions comprises a layer of chrome oxide on a layer of chrome, said chrome layer on said top surface of said substrate;
said second opaque region comprises said layer of chrome oxide on said layer of chrome; and
at least one region of said clear regions comprises a trench formed in said substrate, said trench extending a distance from said top surface of said substrate into said substrate toward said bottom surface of said substrate that is less than a distance between said top and bottom surfaces of said substrate.

8. A method, comprising:
on a substrate transparent to a selected wavelength or wavelengths of radiation, said substrate having a top surface and an opposite bottom surface, defining a printable region and a non-printable region;
forming in said printable region, first opaque regions raised above said top surface of said substrate adjacent to clear regions, each opaque region of said first opaque regions having sidewalls and a top surface;
forming in said non-printable region, a second opaque region raised above said top surface of said substrate, said second opaque region having sidewalls and a top surface; and
forming a capping layer on said sidewalls of said first opaque regions and said sidewalls of said second opaque region.

9. The method of claim 8, further including:
forming said capping layer over said top surfaces of each region of said first opaque regions and said top surface of said second region; and
wherein said capping layer conformably covers said sidewalls of said second opaque region and said top surfaces and sidewalls of each region of said first opaque regions and said top surface and sidewalls of said second opaque region.

10. The photomask of claim 9, wherein said capping layer is transparent to said selected wavelength or wavelengths of radiation.

11. The photomask of claim 8, wherein said capping layer is silicon dioxide.

12. The method of claim 8, wherein:
each region of said first opaque regions comprises a layer of chrome oxide on a layer of chrome, said chrome layer on said top surface of said substrate; and
said second opaque region comprises said layer of chrome oxide on said layer of chrome.

13. The method of claim 8, wherein:
each region of said first opaque regions comprises a layer of molybdenum silicide, said molybdenum silicide layer on said top surface of said substrate; and
said second opaque region comprises a layer of chrome oxide on a layer of chrome on said layer of molybdenum silicide.

14. The photomask of claim 8, wherein:
each region of said first opaque regions comprises a layer of chrome oxide on a layer of chrome, said chrome layer on said top surface of said substrate;
said second opaque region comprises said layer of chrome oxide on said layer of chrome; and
at least one region of said clear regions comprises a trench formed in said substrate, said trench extending a distance from said top surface of said substrate into said substrate toward said bottom surface of said substrate that is less than a distance between said top and bottom surfaces of said substrate.

15. The method of claim 8, wherein said forming said capping layer on said sidewalls of said first opaque regions and said sidewalls of said second opaque region includes forming a conformal capping layer on all exposed surfaces of said substrate and said first and second opaque regions and performing a reactive ion etch to form said capping layer on said sidewalls of said first and second opaque regions.
